(19) United States
(12) Patent Application Publication
(10) Pub. No.: US 2017/0339803 A1
(43) Pub. Date: Nov. 23, 2017

(54) VENTILATOR ARRANGEMENT, FAN FLAP CONFIGURATION AND RELATED CONTROL CABINET

(71) Applicant: AREVA NP SAS, COURBEVOIE (FR)

(72) Inventor: NORMAN KAUN, ERLANGEN (DE)

(21) Appl. No.: 15/662,590

(22) Filed: Jul. 28, 2017

Related U.S. Application Data
(63) Continuation of application No. PCT/EP2016/051726, filed on Jan. 27, 2016.

(30) Foreign Application Priority Data
Jan. 28, 2015 (DE) 102015201478.9

(51) Int. Cl. H05K 7/20

(52) U.S. Cl. CPC H05K 7/20572

(57) ABSTRACT

A fan arrangement has a plurality of fans arranged in parallel to each other and configured to generate airflow along a common main flow direction. A flow channel is assigned to each fan, and a respective flow channel has a flap that can be swiveled between an open position and a closed position. The flap is constructed and positioned within the flow channel in such a way that it is supported by the airflow in the open position and brought into the closed position by a reverse flow opposing the airflow. This arrangement reliably prevents a fluidic short circuit in the event of failure of individual fans, and ensures natural draft convection in the event of failure of all fans. The flap is constructed in such a way that it is brought into the open position when no air is flowing due to its intrinsic weight.

### CROSS-REFERENCE TO RELATED APPLICATION

This is a continuation application, under 35 U.S.C. §120, of copending international application No. PCT/EP2016/051726, filed Jan. 27, 2016, which designated the United States; this application also claims the priority, under 35 U.S.C. §119, of German patent application No. DE 10 2015 201 478.9, filed Jan. 28, 2015; the prior applications are herewith incorporated by reference in their entirety.

### BACKGROUND OF THE INVENTION

### Field of the Invention

The invention concerns a fan arrangement with a plurality of fans arranged in parallel to each other and designed to generate an airflow along a common main flow direction, wherein:
a) at least one flow channel is assigned to each fan,
b) the respective flow channel is provided with a flap that can be swiveled between an open position and a closed position, and
c) the respective flap is constructed and positioned within the flow channel in such a way that it is held or supported by the airflow in the open position and brought into the closed position by means of a reverse flow opposing the airflow.

Furthermore, the invention concerns a control cabinet with such a fan arrangement as well as a fan flap arrangement.

In order to dissipate heat from electronic assemblies that are usually positioned in control cabinets, fans are used. The fans are also called blowers. Frequently, in addition, a plurality of fans is operated in parallel or redundantly to one another. If a plurality of fans is arranged in a plane, in the event of failure of one of the fans, this may result in a fluidic short circuit.

To illustrate this phenomena, reference is made to FIG. 1: there, there are three identical fans built into the upper cover plate of a control cabinet. Normally, if all three fans are in operation, they suck up air on their suction side from below and blow it out of the control cabinet upwards on their air-output side. In doing so, a substantially constant airflow forms, starting from below and traveling upwards (main flow direction) over the cross section of the control cabinet.

Take the case that the middle fan has failed as an example. The flow resistance ΔP₁ is considerably larger that the flow resistance ΔP₂ of the fan that has failed due to the variety of the assemblies built into (but not shown in the illustration) the control cabinet. Therefore, the left and right fan will no longer suck the air from below. A fluidic short circuit results. The left and the right fan will only generate circulating air between the suction side and the air-outlet side, as shown by the flow arrows in FIG. 1. Thereby, the assemblies are no longer cooled by the airflow. As a consequence, this leads to the electrical components on the assemblies heating up considerably. This can lead to failure of the latter, but at least to a reduction of the service life thereof.

To prevent this, in the past blades or flaps assigned to the individual fans that were able to prevent a fluidic short circuit were used. In principle, the solution entails, in the event of an individual fan failing, closing its air channel or flow channel. By means of this, the fans still in operation are hindered from obtaining their suction air through this air channel. Thereby, a fluidic short circuit is prevented. The cooling of the assemblies is ensured.

A disadvantage of these flaps that close as a result of gravity or negative pressure is that, in the event of all fans failing, due to power failure for example, natural convection for maintaining emergency cooling is no longer possible.

In the case of the fan arrangement in accordance with published, non-prosectued German patent application DD 253 722 A1, to which the preamble of the main claim refers, the flaps are each configured and positioned in the flow channel in such a way that they are held in the open position by the airflow generated by the fans and brought into the closed position by a return flown that opposes the airflow. If all the fans fail at the same time, the flaps remain in their open position in which they lean (at an angle of α>90, see FIG. 3) against corresponding stops. Thereby, natural convection can take place through the flow channels. However, this mechanism does not work if the fans fail one after the other or if the flaps fall into the closed position due to vibration or the like during a power failure. Then, they remain closed and prevent or hinder the desired natural convection.

### SUMMARY OF THE INVENTION

The object of the invention is to indicate a fan arrangement of the described type, where, on the one hand, a fluidic short circuit is reliably prevented in the event of failure of individual fans or blowers, and where, on the other hand, natural draft convection is ensured in the event of all fans failing. Thereby, in particular, reliable cooling of control cabinets in all foreseeable operating situations should be achieved.

The indicated object is solved according to the invention by means of a fan arrangement with the features of the main claim.

In accordance therewith, it is crucial to the invention that the respective flap is constructed in such a way that it is brought into the open position when no air is flowing due to its intrinsic weight, if the flap was previously closed.

That means, in the event of all fans failing, if there is a power failure for example, the flaps open automatically in a reliable manner and release the assigned flow channels for natural convection. Even if one or a plurality of flaps was/were previously closed due to the air flow or other circumstances, they open automatically in such exceptional situations and without external aid due to the active force of gravity. This closing function known from the prior art in scenarios with a fluidic short circuit is not impaired due to the resulting/introduced pressure difference or return flow, namely in the event of individual fans failing.

The use of the described fan arrangement in a control cabinet that accommodates, for example, the electric and electronic components or assemblies of a processing system, a machine tool or a production device is particularly advantageous. In this context, control cabinets for the control devices of a nuclear power plant where rudimentary emergency cooling or heat dissipation should be ensured by natural draft convection, even in the event of a so-called station blackout are of particular interest. The fan arrangement according to the invention is preferably positioned in a base or cover plate of such a control cabinet. Naturally, it can also be used for ventilating and cooling other rooms or spatial areas.

For periodic tests, flap monitoring can be provided. By means of an appropriate sensor system combined with a related analysis unit, the current position of the flaps is captured, analyzed and optionally recorded. The sensors should preferably work in a contactless manner in order not to cause any additional friction while the flaps are in motion. In the analysis unit, the captured flap position with the otherwise captured operating state of the assigned fan (for example via electrical parameters) are correlated with one another and an alarm signal is optionally generated.

Other features which are considered as characteristic for the invention are set forth in the appended claims.

Although the invention is illustrated and described herein as embodied in a fan arrangement and related control cabinet, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is an illustration showing a fan arrangement in a control cabinet, wherein flow arrows indicate a fluidic short circuit due to failure of a fan;

FIG. 2 is an illustration showing a section from a fan arrangement with a related flap mechanism to prevent fluidic short circuits, here in a first operating position with open flaps;

FIG. 3 is an illustration showing the fan arrangement in accordance with FIG. 2 in a second operating position with flaps that are closing;

FIG. 4 is an illustration showing the fan arrangement in accordance with FIG. 2 in a third operating position with closed flaps;

FIG. 5 is an illustration showing a similar fan arrangement to that in FIG. 2 in a first operating state with open flaps;

FIG. 6 is an illustration showing the fan arrangement from FIG. 5 in a second operating state with closed flaps; and

FIG. 7 is an illustration showing a control cabinet with the fan arrangement.

### DETAILED DESCRIPTION OF THE INVENTION

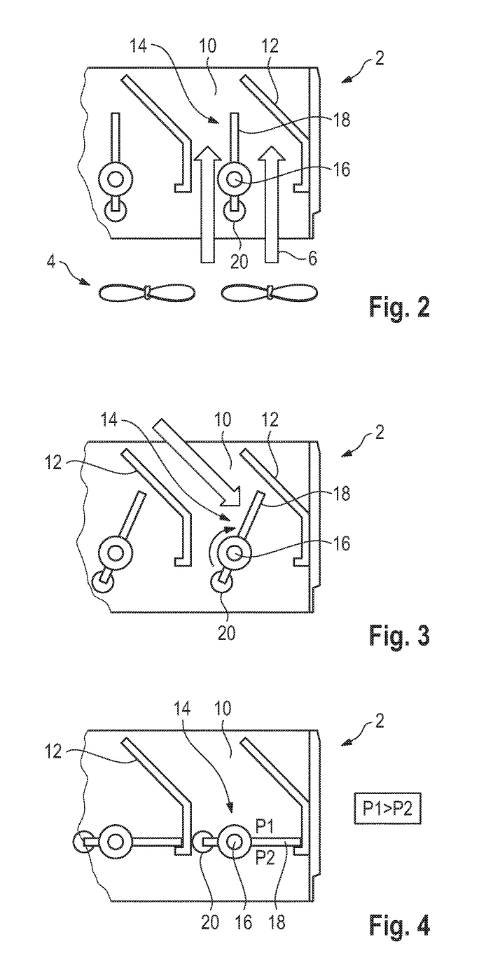

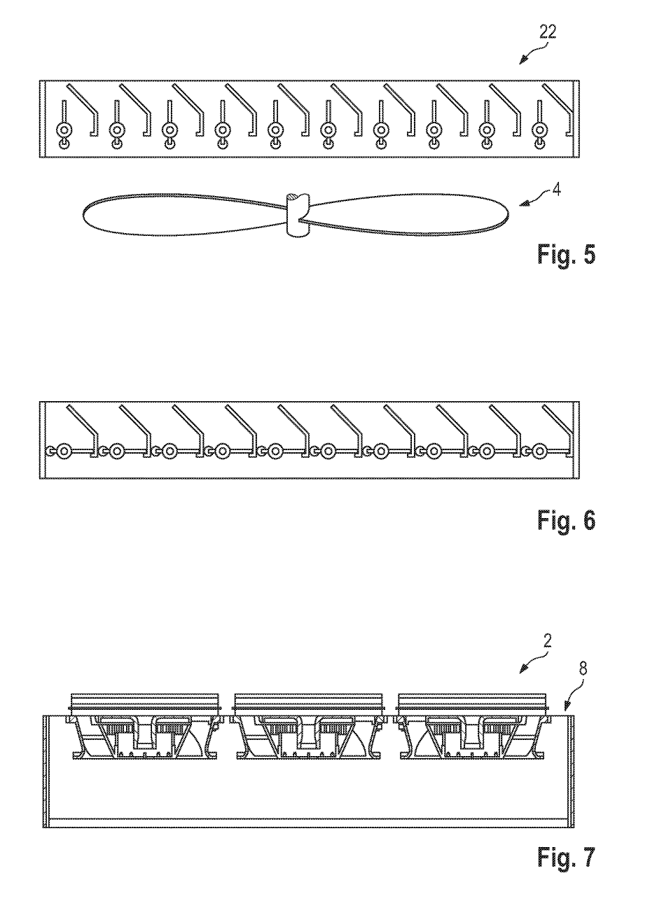

Identical parts or parts with the same effect are provided with the same reference numbers in all figures. In FIGS. 3 and 4, the fans illustrated in FIG. 2 were omitted for the sake of providing a simpler illustration. The same applies to the fan shown in FIG. 5, which has been omitted in the related FIG. 6.

FIG. 2 shows a section through a fan arrangement 2. The fan arrangement 2 includes a plurality of fans 4 arranged adjacent to one another in a horizontal plane. The fans 4 can be arranged at equal distances from one another in a row, for example. A plurality of rows in parallel to one another may be present so that a chess-board-like or grate-type pattern results when viewed from the top. Irregular arrangements are also possible. Preferably, the fans 4 are all identically constructed and respectively driven by electric motors. The fans 4 are schematically illustrated here as axial blowers; other variations, such as radial blowers, can also be used. In normal operation, the rotor blades of the fans 4 each generate an airflow starting from below and traveling upwards (=main flow direction 6). The individual partial flows combine to form an overall flow that serves, for example, for the ventilation and cooling of a spatial area located below the fans 4. In particular, the fan arrangement 2 in accordance with FIG. 7 can be integrated into a cover plate of a control cabinet 8 that accommodates electronic assemblies.

One or a plurality of flow channels 10 are exclusively assigned to each fan 4, and namely with the purpose that the partial flow generated by the fan 4, primarily or at least for the most part, only travels through this precise flow channel 10 or these flow channels 10, but not through the flow channels 10 of the other fans 4. In FIG. 2, a possible arrangement is shown with precisely one assigned flow channel 10 for each fan 4. Another variation where a plurality of flow channels 10 are assigned to each fan 4 is shown in FIG. 5. Here, one has to imagine a plurality of such units each with one fan 4 and related flow channels 10 next to each other in a plane (only one such unit is shown due to a lack of space).

The individual flow channels 10, which are primarily vertically oriented according to the intended main flow direction 6, are at least partially separated from each other by appropriate conductive elements 12 or conductive surfaces. Such conductive elements 12 are also called conductive plates, even though it is not a requirement that these be made of metal. They can also be made of plastic, for example. In accordance with the illustration in FIG. 2, the flow channels 10 are preferably situated above the fans 4. As an alternative, the fans 4 are located inside of the related flow channels 10. In particular, the respective flow channel 10 or a section thereof can be implemented by using a housing that encloses or surrounds the rotor blades of the fan 4. Expediently, all flow channels 10 are configured in the same way and the arrangement of the related fans 4 is also preferably identical for all individual units. Above the flow channels 10, the individual partial flows unite into an overall flow (ventilation flow).

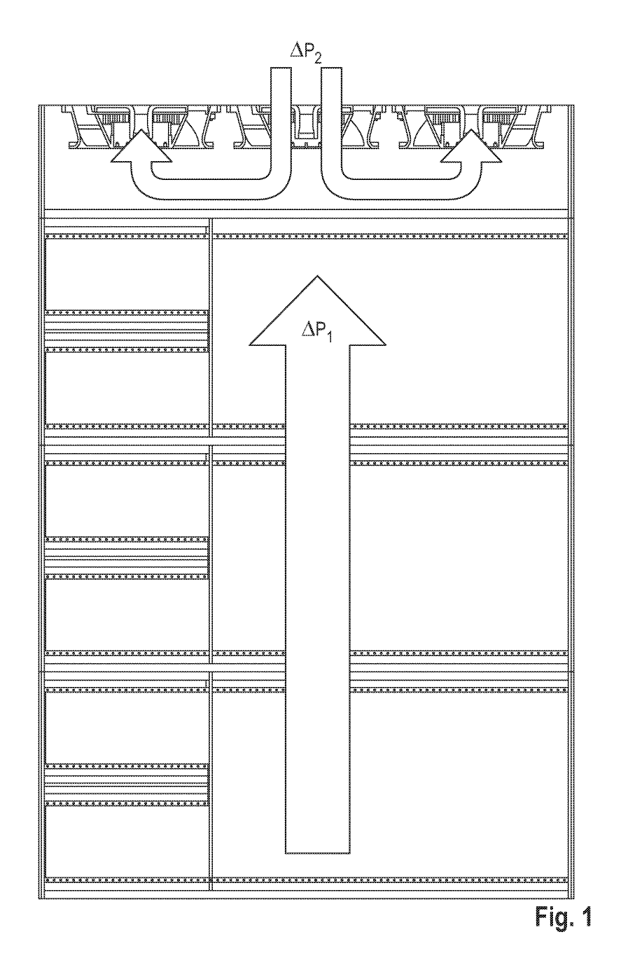

In order to prevent the situation initially described in connection with FIG. 1 of a fluidic short circuit in the event of individual fans failing, each flow channel 10 is equipped with a flap 14 that is also called a back draft damper, using which it can be closed as required, individually and independently of the other flow channels 10.

In the case of the exemplary embodiment shown in the figures, the respective flap 14 is configured in the form of a pendulum flap. It includes a wing-like or lamella-shaped closure element 18 articulated on a horizontal swivel axis or rotary axis 16. Here, the rotary axis 16 is located within the flow channel 10 on the lower end thereof. In the closed position, the closure element 18 is horizontally oriented and primarily closes the cross section of the related flow channel 10 completely (FIG. 4). The air is then blocked from flowing through the flow channel 10. In the open position, the closure element 18 protrudes into the flow channel 10 with a vertical orientation and opposes the airflow that travels through the flow channel 10 via its narrow cross section with a flow resistance that is as little as possible (FIG. 2). Thereby, the airflow generated by the related fan 4 can flow primarily unhindered through the flow channel 10 in the case of this flap position.

Here, the activation or “triggering” of the respective flap 14 takes place automatically and in a completely passive way by taking advantage of intrinsic, failsafe forces, namely the force of weight on the one hand and the force caused by the pressure of the flow on the other hand. To this end, the flap mechanism described in the following is provided.

Therein, it is essential that a counterweight 20, which is connected to the closure element 18 or integrated therein, brings the flap into the open position when no air is flowing. To this end, the masses and the lever lengths of the flap segments (lever arms) that are protruding from the rotary axis 16 on both sides are appropriately selected. The counterweight 20 can also be formed by the closure element 18 itself by appropriate weight distribution in relation to the arrangement of the rotary axes 16. As a result, this means that the flap 14 reliably opens itself due to its intrinsic weight when no air is flowing or almost no air is flowing, if it had incidentally previously been closed, and then stays in the open position. Even in the case of deviations from the resting position, which are coerced due to temporary outer disturbances, the flap 14 continues to return by itself into the open position. Support to keep the flap 14 open is provided by an air flow along the main flow direction 6, starting from below and traveling upwards, as is formed during normal operation of the fan arrangement 2 due to the related fan 4.

To close the respective flap 14, this only occurs in situations with airflow and pressure ratios that cause a return flow through the flow channel 10 opposing the regular flow direction. For this purpose, the conductive elements 12 limiting the respective flow channel 10 are angled at a kinking or bending point in relation to the vertical. Due to the inclined orientation of the flow channel 10 in its upper area, a return flow that is just setting in/occurring encounters the closure element 18 almost perpendicularly or at least with a vertical component and causes a torque in the direction of the closed position. The greater the inclined position of the upper channel section, the greater the closing force ends up being and the more the flow is deflected as well. If the weight ratios are allocated properly, a small closing force is enough to overcome the opening force caused by the intrinsic weight and move the flap 14 into its closed position (rotating/swiveling in the direction of the arrow in accordance with FIG. 3). As long as the air pressure P1 above the flap 14 prevails over the air pressure P2 thereunder, the flap 14 remains securely in the closed position (FIG. 4).

In summary, the following behavior thus results:

During normal operation of the fan arrangement 2, all fans 4 blow air starting from below and traveling upwards. All flaps 14 are open and will be kept open by the airflow.

If a single fan 4 fails, the airflow, which stops due to the fluidic short circuit, makes this precise flap 14 close. A lower pressure accumulates under the closed flap 14 than above it due to the work of the fans still in operation. Thereby, the flap 14 is reliably kept closed.

If all the fans are switched off or if they fail, the pressure difference mentioned also does not come to be. The intrinsic weight/counterweight of the respective flap 14 causes the flap 14 to open on account of gravity. This applies to all flaps 14. A through flow of all flow channels 10 through natural convection is now possible. The convection flow, which generally starts from below and travels upwards, provides support to keep the flaps 14 open.

As has already been mentioned, exactly one flow channel 10 with a flap 14 can be assigned to a fan 4 in a possible implementation in accordance with FIG. 2. As is the case in FIG. 5 however, a plurality of flow channels 10 each having a flap 14 may be assigned to a fan 4. The flaps 14 assigned to a certain fan 4 principally function independently from one another, yet will generally be together in the open position (FIG. 5) or in the closed position (FIG. 6) because the flow ratios are identical for all of them. This variation has the advantage that smaller and lighter flaps 14 with a low level of inertia can be used.

FIG. 7 shows the fan arrangement 2 according to the invention in a cover plate of a control cabinet 8. The details of the respective flap mechanism (flow channels and flaps) were omitted in this illustration, however. Here, the flap mechanism is integrated into the housing of the fans 4 in each case. However, it is also possible that the flap mechanisms form a constructive element in their entirety, namely a fan flap arrangement 22 that can be mounted onto a fan 4 or onto an existing fan arrangement (see FIG. 5).

The following is a summary list of reference numerals and the corresponding structure used in the above description of the invention:

2 Fan arrangement

4 Fan

6 Main flow direction

8 Control cabinet

10 Flow channel

12 Conductive element

14 Flap

16 Rotary axis

18 Closure element

20 Counterweight

22 Fan flap arrangement

1. A ventilator configuration, comprising:
a plurality of ventilators disposed in parallel to each other and configured for generating an air flow along a common main flow direction;
flow channels, at least one of said flow channels is associated with each of said ventilators;
flaps, each of said flow channels is provided with one of said flaps which can be swivelled between an opening position and a closing position, each of said flaps being configured and disposed in one of said flow channels in such a way that in the opening position a flap is supported by air flow, and is put into the closing position by a return flow directed opposite to the air flow, said flap is configured in such a way that in a flowless state, said flap is put into the opening position by a weight of said flap, the common main flow direction being substantially oriented vertically from bottom to top; and
guide elements, said flow channels are separated from each other by said guide elements, each of said guide elements including a vertically oriented section and an obliquely oriented section kinking off from said vertically oriented section, said obliquely oriented section lying above said vertically oriented section, a swivelling axis of each of said flaps is disposed approximately at a level of said vertically oriented section.

2. The ventilator configuration according to claim 1, wherein each of said flaps is a pendulum flap.

3. The ventilator configuration according to claim 1, wherein each of said flaps can be swiveled around a horizontal rotary axis.

4. The ventilator configuration according to claim 1, wherein each of said flaps has a wing-shaped closure element and a counterweight.

5. The ventilator configuration according to claim 4, wherein said wing-shaped closure element is horizontally oriented in the closed position.

6. The ventilator configuration according to claim 4, wherein said wing-shaped closure element is vertically oriented in the open position.

7. The ventilator configuration according to claim 1, wherein said obliquely oriented section being at an incline and lies above said vertically oriented section.

8. The ventilator configuration according to claim 1, wherein all of said flaps are identically constructed.

9. The ventilator configuration according to claim 1, wherein all of said flow channels are identically constructed.

10. The ventilator configuration according to claim 1, wherein all of said flaps are positioned in said flow channels in an equivalent manner.

11. The ventilator configuration according to claim 1, wherein the common main flow direction is primarily oriented in a vertical manner starting from below and traveling upwards.

12. A fan flap configuration, comprising:
a plurality of flow channels disposed in parallel to each another; and
flaps, each of said flow channels is provided with one of said flaps being swivelable between an open position and a closed position, each of said flaps is constructed and positioned within one of said flow channels in such a way that, in an installation position, said flaps are supported by an airflow of an assigned fan in the open position and brought into the closed position by means of a reverse flow opposing the airflow, said flaps are constructed in such a way that said flaps are brought into the open position when no air is flowing due to an intrinsic weight of said flaps.

13. A control cabinet, comprising:
a ventilator configuration according to claim 1; and
a fan flap configuration according to claim 12.
